(19) United States
(12) Patent Application Publication
(10) Pub. No.: US 2014/0030834 A1
(43) Pub. Date: Jan. 30, 2014

(54) FILM-FORMING METHOD AND FILM-FORMING APPARATUS OF ORGANIC LIGHT-EMITTING DIODE

(71) Applicant: Xiaohu Zhao, Guangdong (CN)

(72) Inventor: Xiaohu Zhao, Guangdong (CN)

(73) Assignee: SHENZHEN CHINA STAR OPTELECTRONICS TECHNOLOGY CO., LTD., Guangdong (CN)

(21) Appl. No.: 13/701,801

(22) PCT Filed: Aug. 31, 2012
(86) PCT No.: PCT/CN2012/080830

§ 371 Date: Dec. 3, 2012

(30) Foreign Application Priority Data
Jul. 27, 2012 (CN) 201210264096.3

(51) Int. Cl. H01L 51/00

(52) U.S. Cl. CPC H01L 51/0012
USPC 438/36; 118/723 R; 118/723 E

(57) ABSTRACT

A film-forming method of organic light-emitting diode and a film-forming apparatus are disclosed. The method is to gasify organic materials to gaseous organic molecules and make the gaseous organic molecules to move to a surface of a substrate, and generate an electric field on the surface of the substrate so as to orient the gaseous organic molecules in the same direction. As the gaseous organic molecules contact the surface of the substrate, and the gaseous organic molecules condense to solid organic molecules to form a molecular film, and the solid organic molecules in the molecular film are oriented in the same direction.

### BACKGROUND OF THE INVENTION

1. Field of the Invention

The present invention relates to a field of manufacturing display devices, especially to a film-forming method of organic light-emitting diode and a film-forming apparatus.

2. Description of the Related Art

Organic Electroluminescence Display (OELD) device is a new generation of display device which uses organic light emitting diodes as the light-emitting display components. An organic light emitting diode is to mount an organic light-emitting material between a transparent anode and a metallic reflective cathode, and apply a voltage to the organic light-emitting material to emit lights. Since a organic electroluminescence display device does not require liquid crystal materials and a traditional backlight module, it can be made thinner; and compared with other types of panel display devices, OLED consumes less power, works within a wider range of temperature and costs less to manufacture. Hence, there are more and more applications of OLED. Besides, use organic light-emitting materials with different colors can achieve display of various colors.

With reference to FIG. 1, FIG. 1 is a schematic diagram of the process of forming molecular film in a conventional OLED manufacturing technology.

In a vacuum environment, a heating apparatus 11 (such as a crucible) is used to heat organic materials 12. When being heated, the organic materials 12 turns into gaseous organic molecules 13, and then the gaseous organic molecules 13 move to a surface of a transparent substrate 14. When the gaseous organic molecules 13 contact the transparent substrate 14, the gaseous organic molecules 13 condense into a solid molecular film 15, and the molecular film 15 includes a plurality of solid organic molecules 151.

During the movement of the gaseous organic molecules 13 to the transparent substrate 14, the gaseous organic molecules 13 differ from each other in orientation because the gaseous organic molecules 13 move in an irregular manner. Therefore, when the gaseous organic molecules 13 contact the transparent substrate 14 and turn into the solid organic molecules 151, the solid organic molecules 151 pile up randomly and have different orientations and lead to low carrier mobility of the OLED.

In traditional technologies, the solid organic molecules are modified by chemical treatment so as to make all the solid organic molecules to be oriented in the same direction to further enhance the property of film-forming of the solid organic molecules. However, such a method is time-consuming, inefficiency and costly.

Hence, it is necessary to solve the technical problem existing in the conventional technologies.

### SUMMARY OF THE INVENTION

An object of the present invention is to provide a film-forming method of organic light-emitting diode so as to solve the technical problem in which the modification method of solid organic molecules in traditional technologies is time-consuming, inefficiency and costly.

In order to solve the foregoing problem, the present invention provides a film-forming method of organic light-emitting diode comprising steps of:

using a heating apparatus to heat organic materials so that the organic materials turn into gaseous organic molecules and move to a surface of a substrate; and

providing an electric field generating apparatus, wherein the electric field generating apparatus has a first electrode and a second electrode that are parallel to each other and applies a voltage to the first electrode and the second electrode so as to generate an electric filed on the surface of the substrate, and the electric field orients the gaseous organic molecules in the same direction; and an included angle between a major axis direction of each of the gaseous organic molecules and the direction of the electric field is ranged between 0 degree and 90 degrees; wherein

the gaseous organic molecules that are oriented in the same direction contact the surface of the substrate and condense to form a solid molecular film, wherein solid organic molecules in the molecular film are oriented in the same direction.

In one embodiment of the present invention, the major axis direction of each of the gaseous organic molecules is parallel to the direction of the electric field.

In one embodiment of the present invention, the molecular film is an organic light-emitting layer.

In one embodiment of the present invention, the heating apparatus is a crucible.

Another object of the present invention is to provide a film-forming method of organic light-emitting diode so as to solve the technical problem in which the modification method of solid organic molecules in traditional technologies is time-consuming, inefficiency and costly.

In order to solve the foregoing problem, the present invention provides a film-forming method of organic light-emitting diode comprising steps of:

using a heating apparatus to heat organic materials so that the organic materials turn into gaseous organic molecules and move to a surface of a substrate;

using an electric field generating apparatus to generate an electric field on the surface of the substrate, and the electric field orients the gaseous organic molecules in the same direction; wherein

the gaseous organic molecules that are oriented in the same direction contact the surface of the substrate and condense to solid organic molecules to form a molecular film, wherein the solid organic molecules in the molecular film are oriented in the same direction.

In one embodiment of the present invention, under the effect of the electric field, an included angle between a major axis direction of each of the gaseous organic molecules and the direction of the electric field is ranged between 0 degree and 90 degrees.

In one embodiment of the present invention, the major axis direction of each of the gaseous organic molecules is parallel to the direction of the electric field.

In one embodiment of the present invention, the molecular film is an organic light-emitting layer.

In one embodiment of the present invention, the heating apparatus is a crucible.

In one embodiment of the present invention, the electric field generating apparatus has a first electrode and a second electrode that are parallel to each other; and when a voltage is applied, the first electrode and the second electrode generate the electric filed on the surface of the substrate.

Another object of the present invention is to provide a film-forming apparatus of organic light-emitting diode so as to solve the technical problem in which the modification method of solid organic molecules in traditional technologies is time-consuming, inefficiency and costly.

In order to solve foregoing technical problem, the present invention provides a film-forming apparatus of organic light-emitting diode comprising:

a heating apparatus used for heating organic materials so as to turn the organic materials into gaseous organic molecules, wherein the gaseous organic molecules move to a surface of a bare;

an electric field generating apparatus used to generate an electric field on the surface of the substrate, wherein the electric field orients the gaseous organic molecules in the same direction, and the gaseous organic molecules that are oriented in the same direction contact the surface of the substrate and condense to form a solid molecular film, wherein solid organic molecules in the molecular film are oriented in the same direction.

In one embodiment of the present invention, under the effect of the electric field, an included angle between a major axis direction of each of the gaseous organic molecules and the direction of the electric field is ranged between 0 degree and 90 degrees.

In one embodiment of the present invention, the major axis direction of each of the gaseous organic molecules is parallel to the direction of the electric field.

In one embodiment of the present invention, the electric field generating apparatus has a first electrode and a second electrode that are parallel to each other; and when a voltage is applied, the first electrode and the second electrode generate the electric filed on the surface of the substrate.

Compared with the traditional technology, the present invention is to generate an electric field on a surface of a substrate during the process of vacuum evaporation for forming a molecular film so that gaseous organic molecules can be oriented in the same direction under the effect of the electric field. After the gaseous organic molecules contact the substrate and condense to solid organic molecules, the solid organic molecules can also be oriented in the same direction to form a molecular film which has better uniformity and achieve the maximization of the function of the film, for example, in a hole transporting layer having a transporting function, the organic molecules therein have the highest mobility, or in an organic light-emitting layer having a light-emitting function, the organic molecules therein have lowest mobility.

This invention is detailed described with reference to the following preferred embodiments and the accompanying drawings, where the aforementioned contents of this invention can be made more clear and understandable.

### BRIEF DESCRIPTION OF THE DRAWINGS

FIG. 1 is a schematic diagram of the process of forming molecular film in a conventional OLED manufacturing technology;

FIG. 2 is a flow diagram of a film-forming method of OLED according to a preferred embodiment of the present invention;

FIG. 3 is a schematic diagram of the structure of a film-forming apparatus of OLED for forming a film according to a preferred embodiment of the present invention;

FIG. 4 is a schematic diagram of the structure of a film-forming apparatus of OLED for forming a film according to another preferred embodiment of the present invention;

FIG. 5 is a schematic diagram of the process of forming a film of OLED according to a preferred embodiment of the present invention;

FIG. 6 is a schematic diagram of an included angle between a major axis direction of a gaseous organic molecule and the direction of an electric field according to a preferred embodiment of the present invention;

FIG. 7 is a schematic diagram of the cross-section of the OLED according to a preferred embodiment of the present invention; and

FIG. 8 is a schematic diagram of the process of forming a film of the OLED shown in FIG. 7.

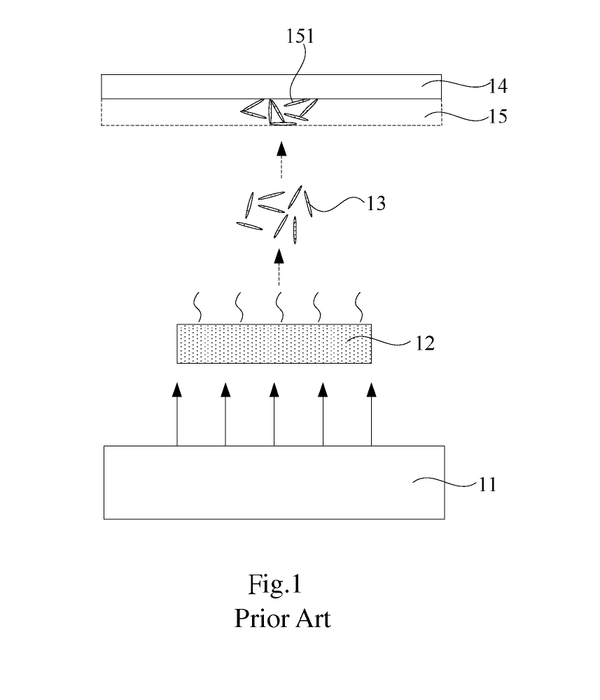

### DETAILED DESCRIPTION OF THE PREFERRED EMBODIMENTS

The foregoing objects, features and advantages adopted by the present invention can be best understood by referring to the following detailed description of the preferred embodiments and the accompanying drawings. Furthermore, the directional terms described in the present invention, such as upper, lower, front, rear, left, right, inner, outer, side and etc., are only directions referring to the accompanying drawings, so that the used directional terms are used to describe and understand the present invention, but the present invention is not limited thereto.

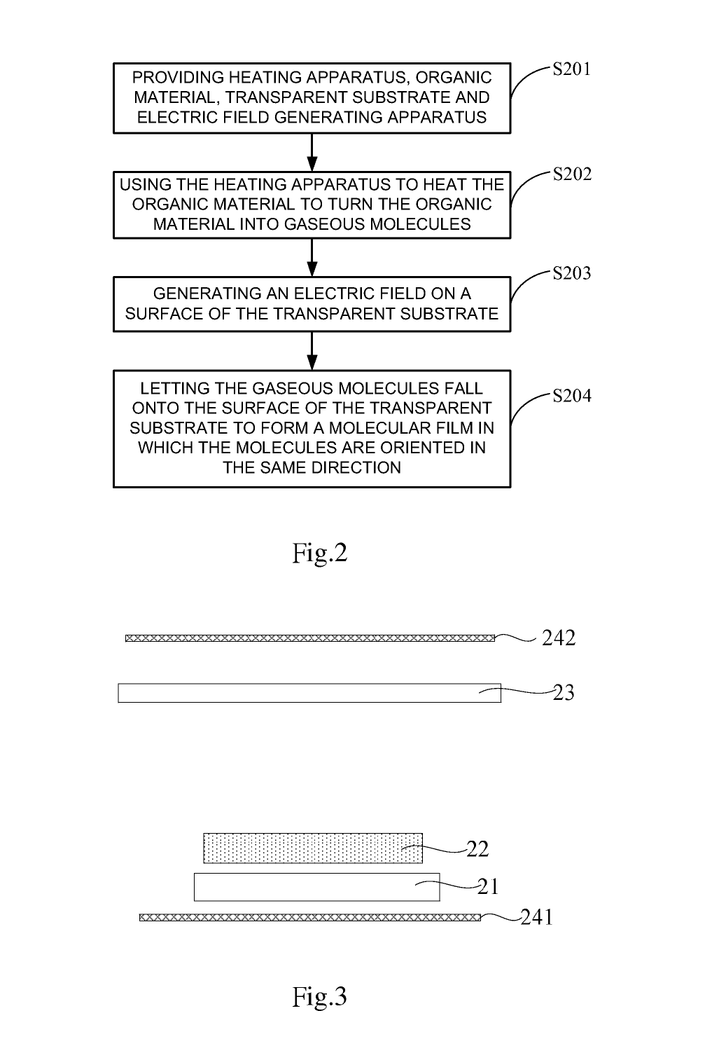

With reference to FIGS. 2 and 3, FIG. 2 is a flow diagram of a film-forming method of OLED according to a preferred embodiment of the present invention and FIG. 3 is a schematic diagram of the structure of a film-forming apparatus of OLED for forming a film according to a preferred embodiment of the present invention.

In step S201, provide a heating apparatus 21, an organic material 22, a transparent substrate 23 and an electric field generating apparatus (not labeled in the figure).

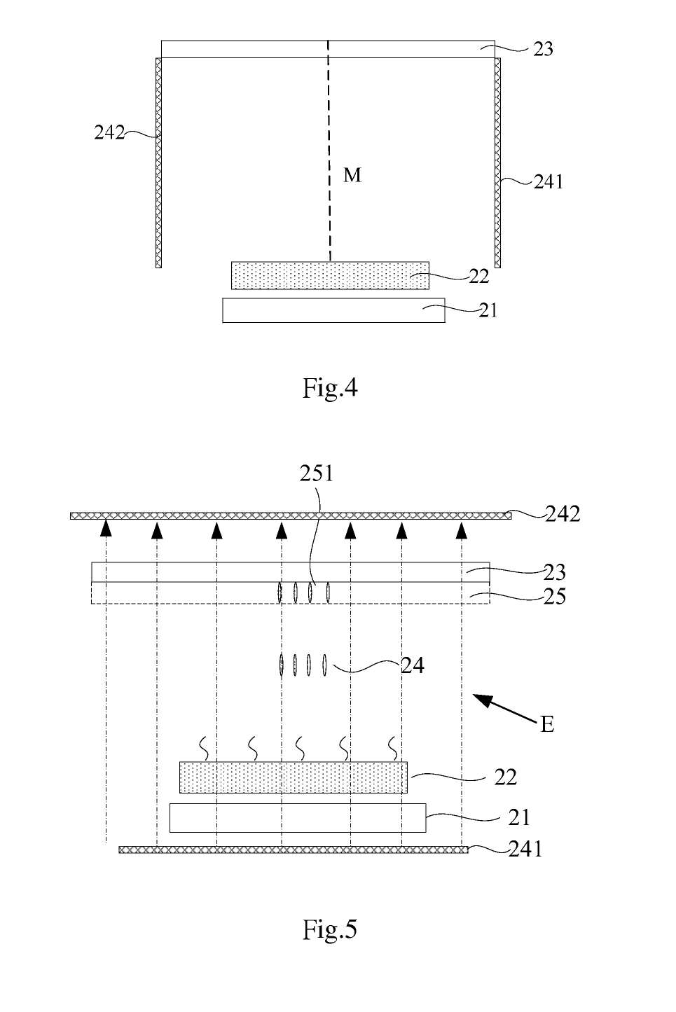

The organic material 22 is mounted between the heating apparatus 21 and transparent substrate 23. The heating apparatus 21 has a first electrode 241 (anode) mounted at a bottom side and has a second electrode 242 (cathode) mounted at a top side, wherein the first electrode 241 and the second electrode 242 construct the electric field generating apparatus of the present invention. In a specific implementation, the first electrode 241 and second electrode 242 may be mounted in other manners. For example, with reference to FIG. 4, the first electrode 241 and the second electrode 242 are mounted at two sides of the connecting line M of the centers of the heating apparatus 21 and the transparent substrate 23. In the followings, the present invention will described using the embodiment in FIG. 3.

In step S202, using the heating apparatus 21 to heat the organic material 22 so as to turn the organic material 22 into gaseous organic molecules 24. The heating apparatus may be a crucible or other heating apparatuses which will not be listed herein.

In step S203, applying a certain voltage to the first electrode 241 and the second electrode 242 so as to generate an electric field E on a surface of the transparent substrate 23. More specifically, it is to generate an electric field E between the transparent substrate 23 and the organic material 22 with further reference to FIG. 5.

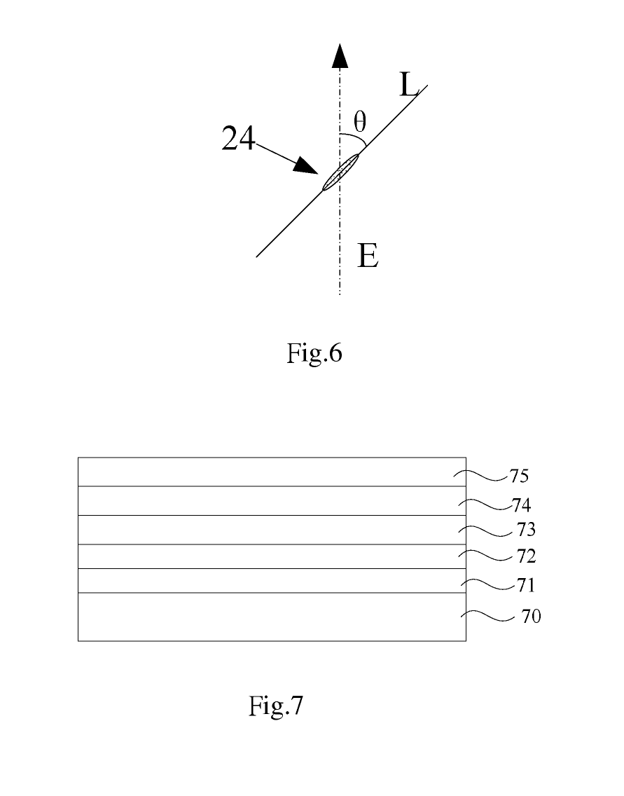

The gaseous organic molecules 24 move to the surface of the transparent substrate 23, and during the movement, the electric field E orients the gaseous organic molecules 24 in the same direction, that is, major axes of the gaseous organic molecules 24 are oriented in the same direction. With further reference to FIG. 6, under the effect of the electric field E, an included angle θ between the major axis L of each of the gaseous organic molecules 24 and the direction of the electric field E is ranged in a predetermined angle range, for example, the included angle θ is ranged between 0 degree and 90 degrees. In the embodiment shown in FIG. 5, the major axis of each of the gaseous organic molecules 24 is parallel to the direction of the electric field E.

In a specific implementation, the step S202 and the step S203 can be performed simultaneously so as to ensure that the gaseous organic molecules 24 generated by heating can be timely influenced by the electric field.

In step S204, the gaseous organic molecules 24 fall onto the surface of the transparent substrate 23 and condense to form a solid molecular film 25.

With further reference to FIG. 5, as the gaseous organic molecules 24 condense to solid organic molecules 251, a large amount of the solid organic molecules 251 then form the molecular film 25, and in the molecular film 25, the solid organic molecules 251 are oriented in the same direction. The included angle between the major axis direction of each of the solid organic molecules 251 in the molecular film 25 and the surface of the transparent substrate 23 is ranged between 0 degree and 90 degrees, for example, all the solid organic molecules 251 are perpendicular to the surface of the transparent substrate 23.

The present invention creates the electric field E in the movement path of the gaseous organic molecules 24 so that under the effect of the electric field E, the gaseous organic molecules 24 can be oriented in the same direction, such as being perpendicular to the surface of transparent substrate 23. After the gaseous organic molecules 24 that are oriented in the same direction contact the surface of the transparent substrate 23 and condense due to cooler temperature, the gaseous organic molecules 24 then turn into solid organic molecules 251 which are oriented in the same direction, and massive solid organic molecules 251 then form a molecular film 25. Apparently, the solid organic molecules 251 in the molecular film 25 are also oriented in the same direction so that the molecular film 25 can exhibit anisotropic electrical conductivity and have better electron mobility, for example, the molecular film 25 can have the highest mobility in the direction of being perpendicular to the transparent substrate 23.

With reference to FIG. 7, FIG. 7 is a schematic diagram of the cross-section of the OLED according to a preferred embodiment of the present invention.

The OLED has a transparent substrate 70, and a first electrode layer 71 (that is, the anode), a hole transporting layer 72, an organic light-emitting layer 73, an electron transport layer 74 and a second electrode layer 75 (that is the cathode) are orderly formed on the transparent substrate 70. Under a condition of applying a bias voltage, the electrons came from the second electrode layer 55 and the holes came from the first electrode layer 51 recombine at the organic light-emitting layer 53 and thereby causing the organic light-emitting layer 53 to emit lights. The lights from the organic light-emitting layer 53 then orderly travel through the hole transporting layer 52, the first electrode layer 51 and the transparent substrate 50.

The molecular film formed by the present invention can be the foregoing organic light-emitting layer 73 or other organic films, such as the hole transporting layer 72 or the electron transport layer 74. The present invention adjusts the structural arrangement of organic molecules of different films in an attempt to achieve the maximization of the function of each of the films. For example, in a hole transporting layer 72 having a transporting function, the organic molecules therein have the highest mobility; in an organic light-emitting layer 73 having a light-emitting function, the organic molecules therein have lowest mobility.

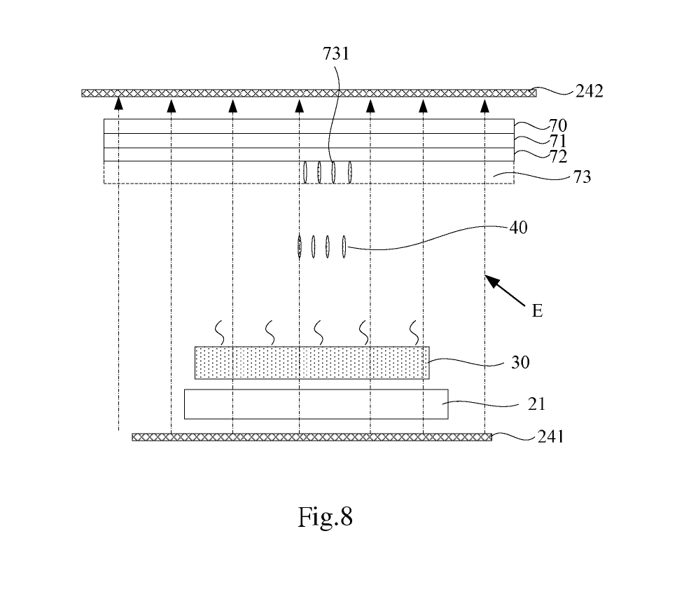

Take forming the organic light-emitting layer 73 as an example, with further reference to FIG. 8, an organic material 30 is provided and heated by the heating apparatus 21 to turn in to gaseous organic molecules 40, and the gaseous organic molecules 40 fall onto the surface of the hole transporting layer 72 to condense to solid organic molecules 731, and massive solid organic molecules 731 form the organic light-emitting layer 73.

During the movement of the gaseous organic molecules 40 moving to the surface of the hole transporting layer 72, the first electrode 241 and the second electrode 242 provide an electric field E in the movement path of the gaseous organic molecules 40. The direction of the electric field E is perpendicular to the hole transporting layer 72 so that the gaseous organic molecules 40 are oriented in the same direction in which the major axis direction of each of the gaseous organic molecules 40 is parallel to the direction of the electric field E.

The solid organic molecules 731 which are formed after the gaseous organic molecules 40 fall onto the surface of the hole transporting layer 72 are also oriented in the same direction, that is the major axis direction of each of the solid organic molecules 731 is perpendicular to the hole transporting layer 72 so that the organic light-emitting layer 73 can exhibit anisotropic electrical conductivity and have better electron mobility.

The present invention generates an electric field on a surface of a substrate during the process of vacuum evaporation for forming a molecular film so that gaseous organic molecules can be oriented in the same direction under the effect of the electric field. After the gaseous organic molecules contact the substrate and condense to solid organic molecules, the solid organic molecules can also be oriented in the same direction to form a molecular film that has better uniformity and achieve the maximization of the function of the film, for example, in a hole transporting layer having a transporting function , the organic molecules therein have the highest mobility, or in an organic light-emitting layer having a light-emitting function, the organic molecules therein have lowest mobility.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A film-forming method of organic light-emitting diode comprising steps of:
using a heating apparatus to heat organic materials so that the organic materials turn into gaseous organic molecules and move to a surface of a substrate; and
providing an electric field generating apparatus, wherein the electric field generating apparatus has a first electrode and a second electrode that are parallel to each other and applies a voltage to the first electrode and the second electrode so as to generate an electric filed on the surface of the substrate, and the electric field orients the gaseous organic molecules in the same direction; and an included angle between a major axis direction of each of the gaseous organic molecules and the direction of the electric field is ranged between 0 degree and 90 degrees; wherein
the gaseous organic molecules that are oriented in the same direction contact the surface of the substrate and condense to form a solid molecular film, wherein solid organic molecules in the molecular film are oriented in the same direction.

2. The film-forming method of organic light-emitting diode as claimed in claim 1, wherein the major axis direction of each of the gaseous organic molecules is parallel to the direction of the electric field.

3. The film-forming method of organic light-emitting diode as claimed in claim 1, wherein the molecular film is an organic light-emitting layer.

4. The film-forming method of organic light-emitting diode as claimed in claim 1, wherein the heating apparatus is a crucible.

5. A film-forming method of organic light-emitting diode comprising steps of:
using a heating apparatus to heat organic materials so that the organic materials turn into gaseous organic molecules and move to a surface of a substrate;
using an electric field generating apparatus to generate an electric field on the surface of the substrate, and the electric field orients the gaseous organic molecules in the same direction; wherein
the gaseous organic molecules that are oriented in the same direction contact the surface of the substrate and condense to solid organic molecules to form a molecular film, wherein the solid organic molecules in the molecular film are oriented in the same direction.

6. The film-forming method of organic light-emitting diode as claimed in claim 5, wherein under the effect of the electric field, an included angle between a major axis direction of each of the gaseous organic molecules and the direction of the electric field is ranged between 0 degree and 90 degrees.

7. The film-forming method of organic light-emitting diode as claimed in claim 6, wherein the major axis direction of each of the gaseous organic molecules is parallel to the direction of the electric field.

8. The film-forming method of organic light-emitting diode as claimed in claim 5, wherein the molecular film is an organic light-emitting layer.

9. The film-forming method of organic light-emitting diode as claimed in claim 5, wherein the heating apparatus is a crucible.

10. The film-forming method of organic light-emitting diode as claimed in claim 5, wherein the electric field generating apparatus has a first electrode and a second electrode that are parallel to each other; and when a voltage is applied, the first electrode and the second electrode generate the electric filed on the surface of the substrate.

11. A film-forming apparatus of organic light-emitting diode comprising:
a heating apparatus used for heating organic materials so as to turn the organic materials into gaseous organic molecules, wherein the gaseous organic molecules move to a surface of a bare;
an electric field generating apparatus used to generate an electric field on the surface of the substrate, wherein the electric field orients the gaseous organic molecules in the same direction, and the gaseous organic molecules that are oriented in the same direction contact the surface of the substrate and condense to form a solid molecular film, wherein solid organic molecules in the molecular film are oriented in the same direction.

12. The film-forming apparatus of organic light-emitting diode as claimed in claim 11, wherein under the effect of the electric field, an included angle between a major axis direction of each of the gaseous organic molecules and the direction of the electric field is ranged between 0 degree and 90 degrees.

13. The film-forming apparatus of organic light-emitting diode as claimed in claim 12, wherein the major axis direction of each of the gaseous organic molecules is parallel to the direction of the electric field.

14. The film-forming apparatus of organic light-emitting diode as claimed in claim 11, wherein the electric field generating apparatus has a first electrode and a second electrode that are parallel to each other; and when a voltage is applied, the first electrode and the second electrode generate the electric filed on the surface of the substrate.
